(19) United States
(12) Patent Application Publication
(10) Pub. No.: US 2024/0147668 A1
(43) Pub. Date: May 2, 2024

(54) HEAT RADIATING MEMBER AND METHOD OF MANUFACTURING THE SAME

(71) Applicant: Samsung Display Co., LTD., Yongin-si (KR)

(72) Inventor: JINKUK CHOI, Yongin-si (KR)

(73) Assignee: Samsung Display Co., LTD., Yongin-si (KR)

(21) Appl. No.: 18/343,893

(22) Filed: Jun. 29, 2023

(30) Foreign Application Priority Data
Oct. 26, 2022 (KR) 10-2022-0139650

(51) Int. Cl. H05K 7/20

(52) U.S. Cl. CPC H05K 7/20336; H05K 7/2099

(57) ABSTRACT

A heat radiating member includes a first plate extending in a first direction and including a first non-folding area, a second non-folding area, and a folding area disposed between the first non-folding area and the second non-folding area and including a plurality of first openings, a second plate extending in the first direction, spaced apart from the first plate in a second direction intersecting the first direction, and including a plurality of second openings in the folding area, and a plurality of pillars disposed between the first plate and the second plate in the first non-folding area and the second non-folding area and connecting the first plate and the second plate. A first separation distance between two adjacent ones of the plurality of first openings and a second separation distance between two adjacent ones of the plurality of second openings are different in the first direction.

### CROSS REFERENCE TO RELATED APPLICATION(S)

This application claims priority to and the benefits of Korean Patent Application No. 10-2022-0139650 under 35 U.S.C. § 119, filed on Oct. 26, 2022, in the Korean Intellectual Property Office (KIPO), the entire contents of which are incorporated herein by reference.

### BACKGROUND

### 1. Technical Field

Embodiments relate to a heat radiating member and a method of manufacturing the same.

### 2. Description of the Related Art

While display devices are gradually becoming smaller, their function is gradually diversifying. Electric devices embedded in the display device may be arranged to be concentrated or in a narrow distance from a peripheral structure as the display device is miniaturized and slimmed, and may generate high-temperature heat due to performing various functions. Such high-temperature heat may cause malfunction of the display device and cause inconvenience to a user. Therefore, the display device may need a heat radiating structure capable of effectively diffusing heat generated from the electric device to the outside.

The display device is manufactured so that a shape of the display device is deformable. For example, a bendable display device, a foldable display device, a rollable display device, and the like have been manufactured and used. Accordingly, it is necessary to manufacture the heat radiating structure to be deformable.

### SUMMARY

Embodiments provide a heat radiating member having improved quality.

Embodiments provide a method of manufacturing the heat radiating member.

A heat radiating member according to an embodiment may include a first plate extending in a first direction and including a first non-folding area, a second non-folding area, and a folding area disposed between the first non-folding area and the second non-folding area and including a plurality of first openings, a second plate extending in the first direction, spaced apart from the first plate in a second direction intersecting the first direction, and including a plurality of second openings in the folding area, and a plurality of pillars disposed between the first plate and the second plate in the first non-folding area and the second non-folding area and connecting the first plate and the second plate. A first separation distance between two adjacent ones of the plurality of first openings and a second separation distance between two adjacent ones of the plurality of second openings may be different in the first direction.

In an embodiment, the heat radiating member may further include a wick structure disposed between the first plate and the second plate, extending in the first direction, and including a plurality of third openings in the folding area.

In an embodiment, a third separation distance between two adjacent ones of the plurality of third openings may be greater than the second separation distance and less than the first separation distance in the first direction.

In an embodiment, the first plate and the second plate may be folded with respect to a folding axis, and a distance between the folding axis and the first plate may be greater than a distance between the folding axis and the second plate.

In an embodiment, the first separation distance may be greater than the second separation distance.

In an embodiment, the heat radiating member may further include a first film attached to an upper surface and a lower surface of a portion of the first plate in the folding area, a second film attached to an upper surface and a lower surface of a portion of the second plate in the folding area, and a third film attached to an upper surface and a lower surface of a portion of the wick structure in the folding area.

In an embodiment, the first film and the second film may include thermoplastic polyurethane.

In an embodiment, a portion of the wick structure in the first non-folding area and the second non-folding area may include a mesh structure.

In an embodiment, the plurality of pillars may penetrate the wick structure.

A heat radiating member according to an embodiment may include a first plate extending in a first direction and including a first non-folding area, a second non-folding area, and a folding area disposed between the first non-folding area and the second non-folding area and including a plurality of first openings, a second plate extending in the first direction, spaced apart from the first plate in a second direction intersecting the first direction, and including a plurality of second openings in the folding area, and a plurality of pillars disposed between the first plate and the second plate in the first non-folding area and the second non-folding area and connecting the first plate and the second plate. A width of each of the plurality of second openings may be different from a width of each of the plurality of first openings in the first direction.

In an embodiment, the heat radiating member may further include a wick structure disposed between the first plate and the second plate, extending in the first direction, and including a plurality of third openings in the folding area.

In an embodiment, a width of each of the plurality of third openings may be greater than the width of each of the plurality of second openings and less than the width of each of the plurality of first openings in the first direction.

In an embodiment, the first plate and the second plate may be folded with respect to a folding axis, and a distance between the folding axis and the first plate may be greater than a distance between the folding axis and the second plate.

In an embodiment, the width of each of the plurality of first openings may be greater than the width of each of the plurality of second openings.

A method of manufacturing a heat radiating member according to an embodiment may include forming a first preliminary plate extending in a first direction, forming a first plate including a first non-folding area, a second non-folding area, and a folding area disposed between the first non-folding area and the second non-folding area and including a plurality of first openings by patterning a first portion of the first preliminary plate, forming a plurality of pillars extending in a second direction intersecting the first direction on the first plate in the first non-folding area and the second non-folding area, forming a preliminary wick structure extending in the first direction, forming a wick structure including a plurality of third openings in the folding area by patterning a third portion of the preliminary wick structure, forming a second preliminary plate extending in the first direction, forming a second plate including a plurality of second openings in the folding area by patterning a second portion of the second preliminary plate, disposing the wick structure on the first plate so that the plurality of pillars pass through the wick structure, and disposing the second plate on the plurality of pillars. A first separation distance between two adjacent ones of the plurality of first openings and a second separation distance between two adjacent ones of the plurality of second openings may be different in the first direction.

In an embodiment, the method may further include attaching a first film to an upper surface and a lower surface of a portion of the first plate in the folding area, attaching a second film to an upper surface and a lower surface of a portion of the second plate overlapping the folding area, and attaching a third film to an upper surface and a lower surface of a portion of the wick structure in the folding area.

In an embodiment, the forming of the first plate may include forming a first hard mask on the first preliminary plate, patterning a portion of the first hard mask overlapping the first portion of the folding area in a thickness direction of the heat radiating member, etching the first preliminary plate, and removing the first hard mask.

In an embodiment, the forming of the wick structure may include forming a second hard mask on the preliminary wick structure, patterning a portion of the second hard mask in the third portion of the folding area, etching the preliminary wick structure, and removing the second hard mask.

In an embodiment, the forming of the second plate may include forming a second hard mask on the second preliminary plate, patterning a portion of the second hard mask in the second portion of the folding area, etching the second preliminary plate, and removing the second hard mask.

In an embodiment, the first separation distance may be greater than the second separation distance.

A heat radiating member according to an embodiment may include a first plate extending in a first direction and including a first non-folding area, a second non-folding area, and a folding area disposed between the first non-folding area and the second non-folding area and including a plurality of first openings, a second plate extending in the first direction, spaced apart from the first plate in a second direction intersecting the first direction, and including a plurality of second openings in the folding area, and a plurality of pillars disposed between the first plate and the second plate in the first non-folding area and the second non-folding area and connecting the first plate and the second plate between the first plate and the second plate. A first separation distance between two adjacent ones of the plurality of first openings and a second separation distance between two adjacent ones of the plurality of second openings may be different in the first direction.

Accordingly, even if a display device is manufactured to be deformable, such as a foldable display device or a rollable display device, a heat radiating member may be securely attached to the display device.

### BRIEF DESCRIPTION OF THE DRAWINGS

Illustrative, non-limiting embodiments will be more clearly understood from the following detailed description in conjunction with the accompanying drawings.

FIG. 1 is a schematic rear view illustrating a heat radiating member and a display device according to an embodiment.

FIG. 2 is a schematic side view of a foldable display device to which the heat radiating member of FIG. 1 is applied.

FIG. 3 is a schematic cross-sectional view illustrating the heat radiating member of FIG. 1 according to an embodiment.

FIG. 4 is a schematic cross-sectional view illustrating a portion of the heat radiating member of FIG. 3 in a folding area.

FIG. 5 is a schematic cross-sectional view illustrating a heat radiating member of FIG. 1 according to another embodiment.

FIG. 6 is a schematic cross-sectional view illustrating a portion of the heat radiating member of FIG. 5 in the folding area.

FIGS. 7 to 19 are schematic cross-sectional views illustrating a method of manufacturing the heat radiating member of FIG. 3 according to an embodiment.

FIGS. 20 and 21 are schematic views illustrating a multi-foldable display device with the heat radiating member of FIG. 1 according to an embodiment.

FIG. 22 is a schematic view illustrating a rollable display device with the heat radiating member of FIG. 1 according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

The first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ.

When a component is described herein to “connect” another component to the other component or to be “connected to” other components, the components may be connected to each other as separate elements, or the components may be integral with each other.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a plane or on a plane” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Hereinafter, display devices in accordance with embodiments will be described in more detail with reference to the accompanying drawings. The same reference numerals are used for the same components in the drawings, and redundant descriptions of the same components will be omitted.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

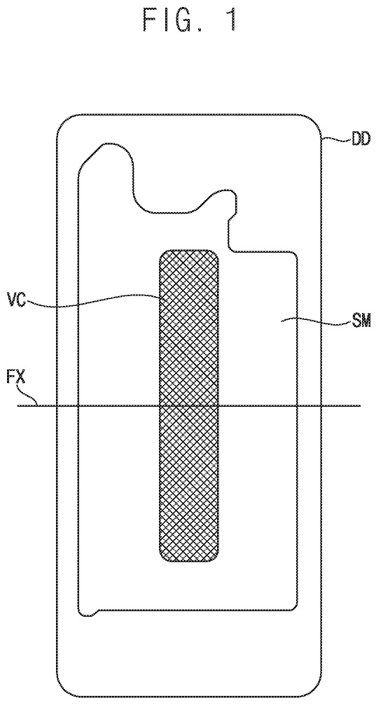

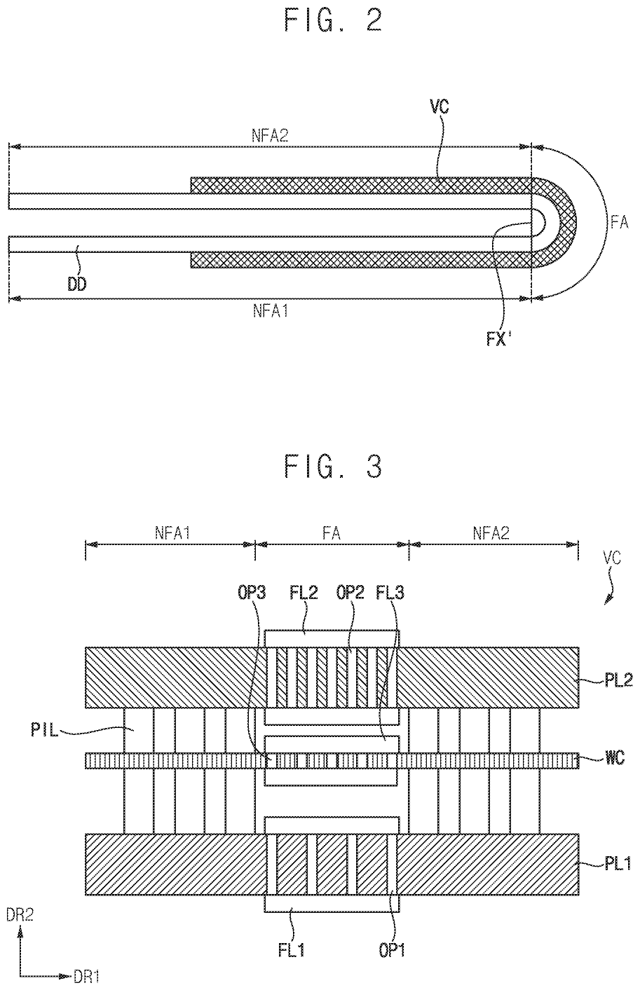

FIG. 1 is a schematic rear view illustrating a heat radiating member and a display device according to an embodiment. FIG. 2 is a schematic side view of a foldable display device to which the heat radiating member of FIG. 1 is applied.

Referring to FIG. 1, a heat radiating member VC may be disposed on a support member SM embedded in a display device DD. In an embodiment, the heat radiating member VC may be disposed in a manner that is at least partially penetrated or accommodated in a recess (not shown) formed in the support member SM. The display device DD may include a substrate (not shown) and a battery (not shown) disposed under the support member SM.

The display device may include multiple electrical or electronic elements on the substrate. For example, the display device may include a processor, an interface, and/or a memory. In an embodiment, the processor may include at least one of a central processing unit, a graphic processing unit, a sensor hub processor, an image signal processor, and a communication processor.

In an embodiment, the interface may include at least one of a high definition multimedia interface (HDMI), a universal serial bus (USB) interface, an SD card interface, and an audio interface. In an embodiment, the memory may include at least one of volatile memory and non-volatile memory.

The battery may supply power to the electrical or electronic elements. In an embodiment, the battery may include a non-rechargeable primary battery, a rechargeable secondary battery, or a fuel cell. In an embodiment, the battery and the substrate may be disposed substantially on a same plane. In an embodiment, the battery may be detachably disposed from the display device DD.

The heat radiating member VC may rapidly diffuse heat generated from the electronic devices to a periphery portion of the support member SM. In an embodiment, the display device DD may be in-folded or out-folded based on a folding axis FX. The heat radiating member VC may also be in-folded or out-folded based on the folding axis FX.

Referring to FIG. 2, the display device DD may be a foldable display device. The display device DD may include a first non-folding area NFA1, a second non-folding area NFA2, and a folding area FA disposed between the first non-folding area NFA1 and the second non-folding area NFA2. For example, the first non-folding area NFA1 and the second non-folding area NFA2 may be spaced apart from each other with the folding area FA interposed between the first non-folding area NFA1 and the second non-folding area NFA2. The display device DD may be folded with respect to a folding axis FX′. As the folding area FA is folded, the display device DD may be folded, and the first non-folding area NFA1 and the second non-folding area NFA2 may not be folded.

As the display device DD is folded, the heat radiating member VC may also be folded. For example, the heat radiating member VC may be folded based on the folding axis FX′. As a portion of the heat radiating member VC in the folding area FA is folded, the heat radiating member VC may be folded. A portion of the heat radiating member VC in the first non-folding area NFA1 and the second non-folding area NFA2 may not be folded.

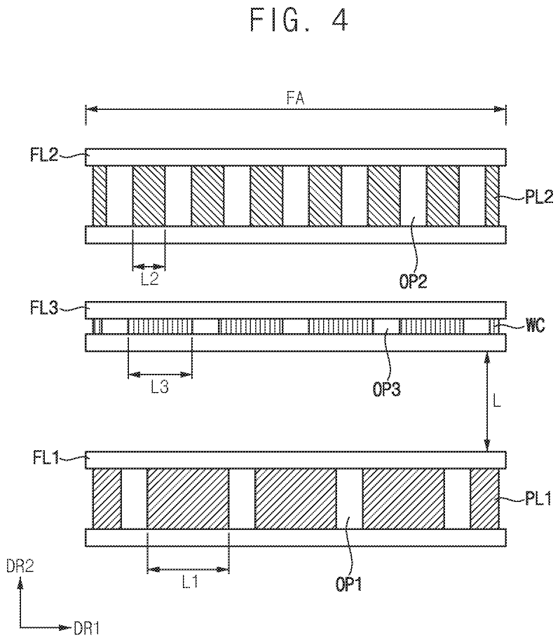

FIG. 3 is a schematic cross-sectional view illustrating the heat radiating member of FIG. 1 according to an embodiment. FIG. 4 is a schematic cross-sectional view illustrating a portion of the heat radiating member of FIG. 3 in a folding area.

Referring to FIG. 3, the heat radiating member VC according to an embodiment may include a first plate PL1, a wick structure WC, a second plate PL2, a first film FL1, a second film FL2, a third film FL3, and multiple pillars PIL.

The first plate PL1 may include a first non-folding area NFA1, a second non-folding area NFA2, and a folding area FA disposed between the first non-folding area NFA1 and the second non-folding area NFA2 and including multiple first openings OP1. The first plate PL1 may extend in a first direction DR1.

The second plate PL2 may extend in the first direction DR1. The second plate PL2 may be spaced apart from the first plate PL1 in a second direction DR2 intersecting the first direction DR1. The second plate PL2 may include multiple second openings OP2 in the folding area FA.

Referring to FIG. 4, in an embodiment, a second separation distance L2 between two adjacent second openings OP2 and a first separation distance L1 between two adjacent first openings OP1 may be different.

In an embodiment, the first plate PL1 and the second plate PL2 may include a copper alloy, a low carbon stainless steel, a titanium alloy, the like, or a combination thereof. A material of each of the first plate PL1 and the second plate PL2 may be used alone or in a combination with each other.

For example, ends of the first plate PL1 and the second plate PL2 may be bonded to form an inner space of the heat radiating member VC.

The wick structure WC may be disposed between the first plate PL1 and the second plate PL2. The wick structure WC may extend in the first direction DR1. The wick structure WC may include multiple third openings OP3 in the folding area FA.

In an embodiment, a portion of the wick structure WC in the first non-folding area NFA1 and the second non-folding area NFA2 may include a mesh structure. In an embodiment, the mesh structure may be formed of a screen mesh. In an embodiment, the screen mesh of the mesh structure may be made of copper or the like. In an embodiment, a working fluid of the wick structure WC may include water or the like.

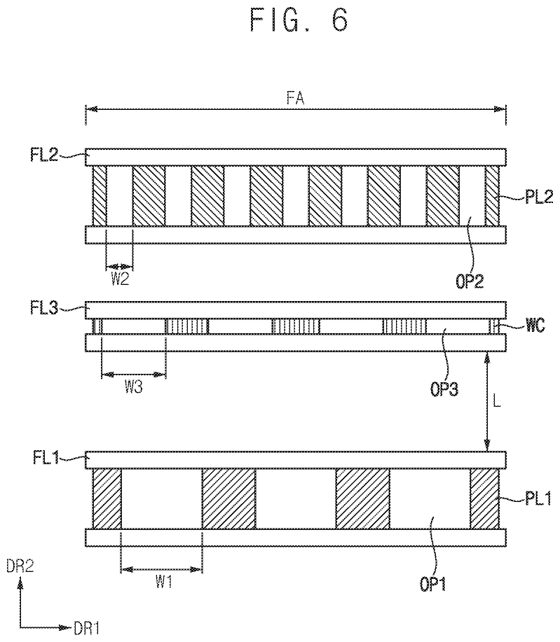

In an embodiment, the wick structure WC may be disposed (e.g., directly disposed) on an upper surface of the first plate PL1. For example, a distance (see, e.g., distance L of FIGS. 4 and 6) between the first plate PL1 and the wick structure WC of FIG. 4 may be about 0.

Multiple pillars PIL may be disposed in the first non-folding area NFA1 and the second non-folding area NFA2. For example, the pillars PIL may not be disposed in the folding area FA. Since the heat radiating member VC is folded by folding a portion of the heat radiating member VC in the folding area FA, the pillars PIL may not be disposed in the folding area FA, and a flexibility of the heat radiating member VC may be increased.

In an embodiment, the pillars PIL may include copper or the like. In an embodiment, the pillars PIL may connect the first plate PL1 and the second plate PL2 between the first plate PL1 and the second plate PL2. In an embodiment, multiple pillars PIL may penetrate (or pass through) the wick structure WC.

A first film FL1 may be attached to upper and lower surfaces of a portion of the first plate PL1 in the folding area FA. A second film FL2 may be attached to upper and lower surfaces of a portion of the second plate PL2 in the folding area FA. A third film FL3 may be attached to upper and lower surfaces of a portion of the wick structure WC in the folding area FA.

In an embodiment, each of the first film FL1, the second film FL2, and the third film FL3 may include a polymer compound. In an embodiment, each of the first film FL1, the second film FL2, and the third film FL3 may include thermoplastic polyurethane or the like. The inner space of the heat radiating member VC made by bonding the first plate PL1 and the second plate PL2 of the heat radiating member VC may be sealed by the first film FL1 and the second film FL2.

Referring to FIGS. 3 and 4, in case that the heat radiating member VC is folded, the first non-folding area NFA1 and the second non-folding area NFA2 of the second plate PL2 may face each other. In an embodiment, in case that the first plate PL1 and the second plate PL2 are folded with respect to a folding axis (see, e.g., the folding axis FX′ of FIG. 2 disposed on the second plate PL2), a distance between the folding axis and the first plate PL1 may be greater than a distance between the folding axis and the second plate PL2.

The first separation distance L1 may be greater than the second separation distance L2. The third separation distance L3 between two adjacent third openings OP3 may be greater than the second separation distance L2 and less than the first separation distance L1.

In case that the heat radiating member VC is folded, the first non-folding area NFA1 and the second non-folding area NFA2 of the first plate PL1 may be folded to face each other. In another embodiment, in case that the first plate PL1 and the second plate PL2 are folded with respect to another folding axis (e.g., a folding axis disposed on the first plate PL1), a distance between the folding axis and the first plate PL1 may be less than a distance between the folding axis and the second plate PL2.

The first separation distance L1 may be less than the second separation distance L2. The third separation distance L3 may be less than the second separation distance L2 and greater than the first separation distance L1.

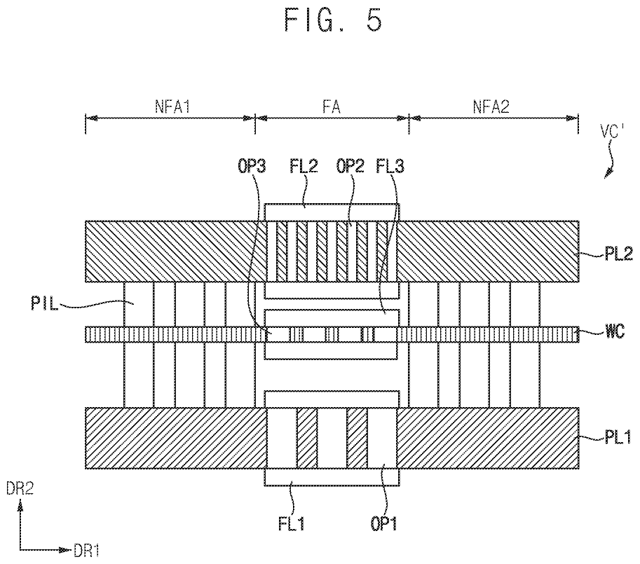

FIG. 5 is a schematic cross-sectional view illustrating a heat radiating member of FIG. 1 according to another embodiment. FIG. 6 is a schematic cross-sectional view illustrating a portion of the heat radiating member of FIG. 5 in the folding area.

In case that a heat radiating member VC′ of FIGS. 5 and 6 is described, substantially same components as the heat radiating member VC of FIGS. 3 and 4 may be denoted by same reference numerals, and a detailed description thereof may be omitted.

Referring to FIGS. 5 and 6, the heat radiating member VC′ according to another embodiment may include a first plate PL1, a wick structure WC, a second plate PL2, a first film FL1, a second film FL2, a third film FL3, and multiple pillars PIL.

The first plate PL1 may include a first non-folding area NFA1, a second non-folding area NFA2, and a folding area FA disposed between the first non-folding area NFA1 and the second non-folding area NFA2 and including multiple first openings OP1. The first plate PL1 may extend in a first direction DR1.

The second plate PL2 may extend in the first direction DR1. The second plate PL2 may be spaced apart from the first plate PL1 in a second direction DR2 intersecting the first direction DR1. The second plate PL2 may include multiple second openings OP2 in the folding area FA. In an embodiment, a width W2 of each of the second openings OP2 and a width W1 of each of the first openings OP1 may be different.

The wick structure WC may be disposed between the first plate PL1 and the second plate PL2. The wick structure WC may extend in the first direction DR1. The wick structure WC may include multiple third openings OP3 in the folding area FA.

Multiple pillars PIL may be disposed in the first non-folding area NFA1 and the second non-folding area NFA2. For example, the pillars PIL may not be disposed in the folding area FA. Since the heat radiating member VC′ is folded by folding a portion of the heat radiating member VC′ in the folding area FA, the pillars PIL may not be disposed in the folding area FA, and a flexibility of the heat radiating member VC′ may be increased.

A first film FL1 may be attached to upper and lower surfaces of a portion of the first plate PL1 in the folding area FA. A second film FL2 may be attached to the upper and lower surfaces of the portion of the second plate PL2 in the folding area FA. A third film FL3 may be attached to upper and lower surfaces of a portion of the wick structure WC in the folding area FA.

In case that the heat radiating member VC′ is folded, the first non-folding area NFA1 and the second non-folding area NFA2 of the second plate PL2 may face each other. In an embodiment, in case that the first plate PL1 and the second plate PL2 are folded with respect to the folding axis (see, e.g., the folding axis FX′ of FIG. 2 disposed on the second plate PL2), a distance between the folding axis and the first plate PL1 may be greater than a distance between the folding axis and the second plate PL2.

The width W1 of each of the first openings OP1 may be greater than the width W2 of the second openings OP2. The width W3 of the third openings OP3 may be greater than the width W2 of the second openings OP2 and less than the width W1 of each of the first openings OP1.

In case that the heat radiating member VC′ is folded, the first non-folding area NFA1 and the second non-folding area NFA2 of the first plate PL1 may face each other. In another embodiment, in case that the first plate PL1 and the second plate PL2 are folded with respect to a folding axis (e.g., a folding axis disposed on the first plate PL1), a distance between the folding axis and the first plate PL1 may be less than a distance between the folding axis and the second plate PL2.

The width W1 of each of the first openings OP1 may be less than the width W2 of each of the second openings OP2. The width W3 of each of the third openings OP3 may be less than the width W2 of each of the second openings OP2 and greater than the width W1 of each of the first openings OP1.

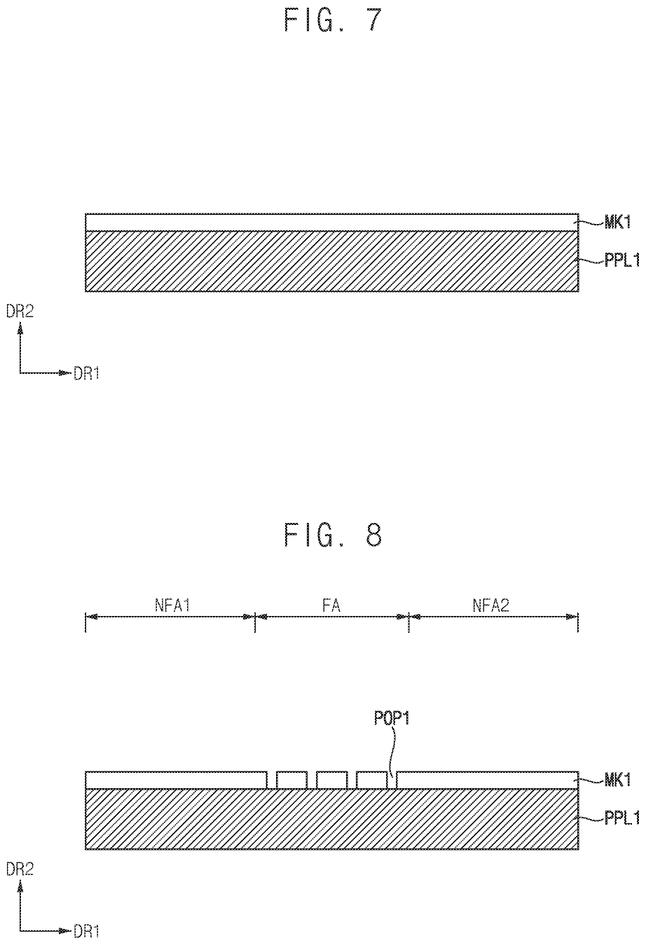

FIGS. 7 to 19 are schematic cross-sectional views illustrating a method of manufacturing the heat radiating member of FIG. 3 according to an embodiment.

Referring to FIGS. 7 and 8, a first hard mask MK1 may be formed on a first preliminary plate PPL1. In an embodiment, the first preliminary plate PPL1 may include at least one of a copper alloy, a low carbon stainless steel, a titanium alloy, the like, and a combination thereof. In an embodiment, the first hard mask MK1 may be formed using a metal. After forming the first hard mask MK1, multiple first preliminary openings POP1 may be formed by patterning a portion of the first hard mask MK1 in the folding area FA.

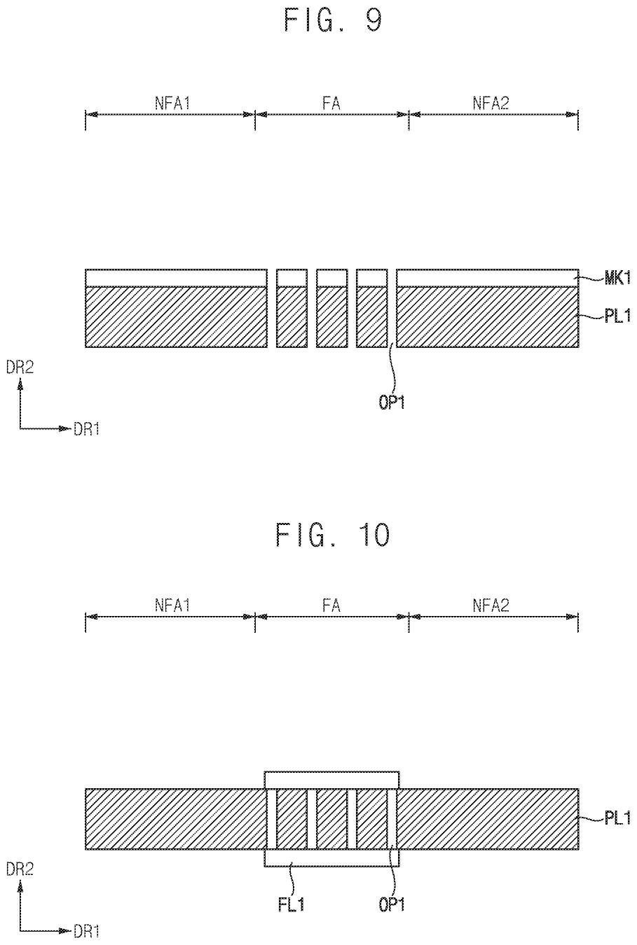

Referring to FIG. 9, multiple first openings OP1 may be formed by removing a first portion of the exposed first preliminary plate (see, e.g., the first preliminary plate PPL1 of FIG. 8) that does not overlap the patterned first hard mask MK1 in a thickness direction of the heat radiating member VC. In an embodiment, the first portion of the first preliminary plate PPL1 may be removed through an etching process. After forming the first openings OP1, the first hard mask MK1 may be removed.

Referring to FIGS. 10 and 11, a first film FL1 may be attached to upper and lower surfaces of a portion of the first plate PL1 in the folding area FA. Multiple pillars PIL extending in a second direction DR2 intersecting the first direction DR1 may be formed on the first plate PL1. The pillars PIL may be formed in the first non-folding area NFA1 and the second non-folding area NFA2. For example, the pillars PIL may not be disposed in the folding area FA. In an embodiment, the pillars PIL may include copper or the like.

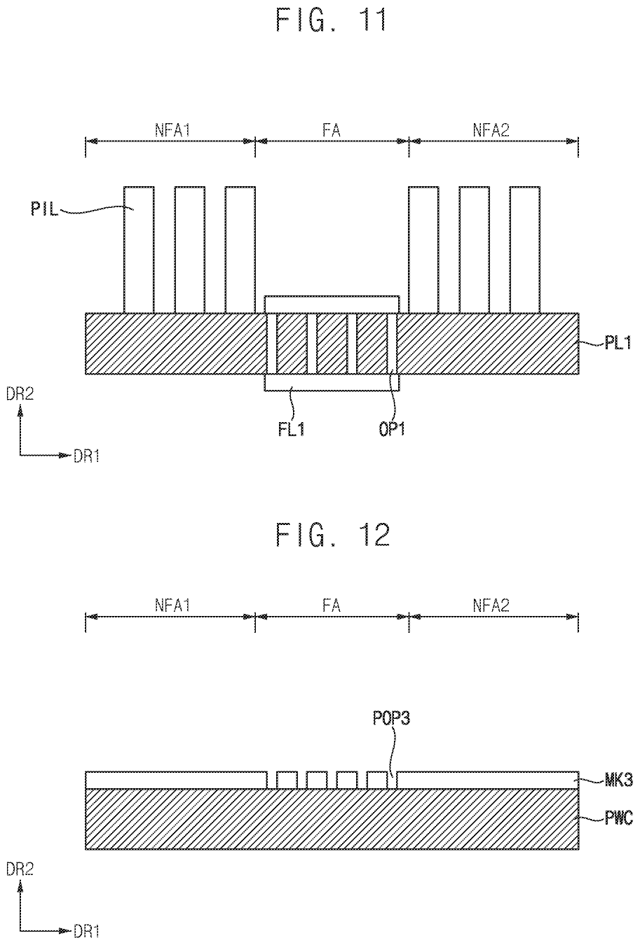

Referring to FIG. 12, a third hard mask MK3 may be formed on a preliminary wick structure PWC. In an embodiment, a portion of the preliminary wick structure PWC in the first non-folding area NFA1 and the second non-folding area NFA2 may include a mesh structure. In an embodiment, the mesh structure may be formed of a screen mesh. In an embodiment, the screen mesh of the mesh structure may be made of copper or the like. In an embodiment, a working fluid of the preliminary wick structure PWC may include water or the like.

In an embodiment, the third hard mask MK3 may be formed using a metal. After forming the third hard mask MK3, multiple third preliminary openings POP3 may be formed by patterning a portion of the third hard mask MK3 in the folding area FA.

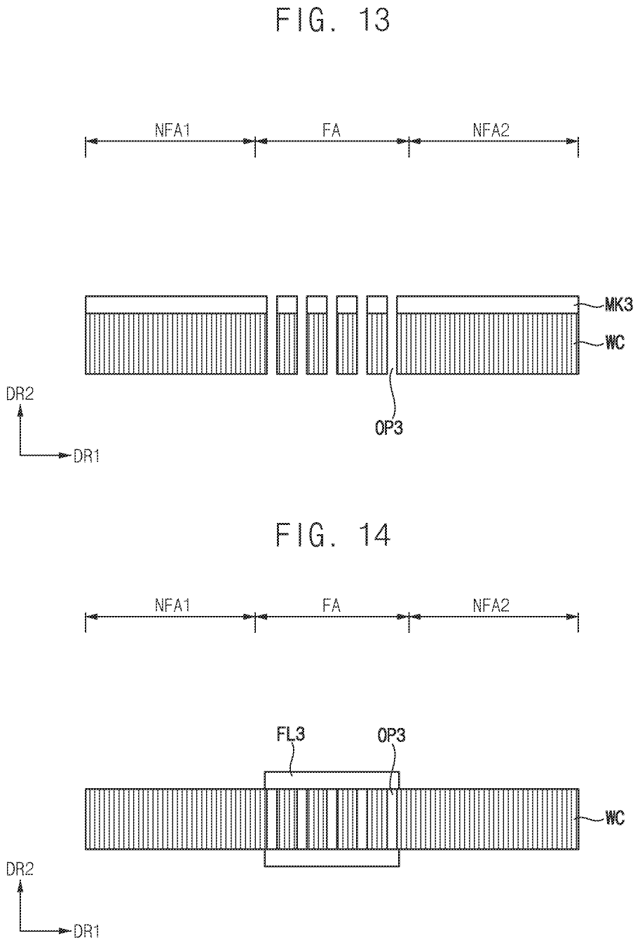

Referring to FIG. 13, multiple third openings OP3 may be formed by removing a third portion of the exposed preliminary wick structure (see, e.g., the preliminary wick structure PWC of FIG. 12) that does not overlap the patterned third hard mask MK3. In an embodiment, the third portion of the preliminary wick structure may be removed through an etching process. After forming the third openings OP3, the third hard mask MK3 may be removed.

Referring to FIG. 14, a third film FL3 may be attached to upper and lower surfaces of a portion of the wick structure WC in the folding area FA.

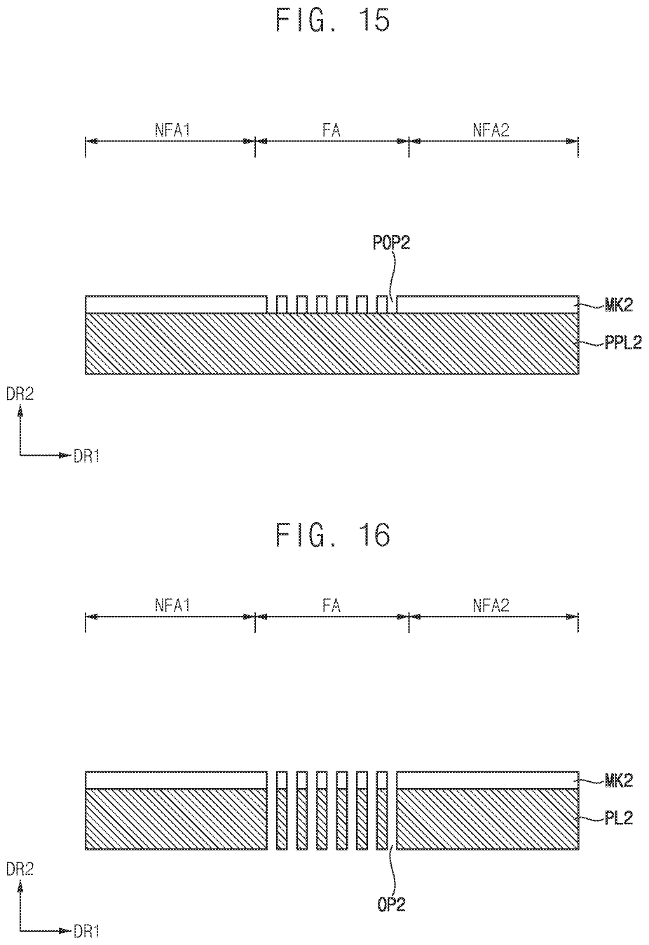

Referring to FIG. 15, a second hard mask MK2 may be formed on a second preliminary plate PPL2. In an embodiment, the second preliminary plate PPL2 may include at least one of a copper alloy, a low carbon stainless steel, a titanium alloy, the like, and a combination thereof. In an embodiment, the second hard mask MK2 may be formed using a metal. After forming the second hard mask MK2, multiple second preliminary openings POP2 may be formed by patterning a portion of the second hard mask MK2 in the folding area FA.

Referring to FIG. 16, multiple second openings OP2 may be formed by removing a second portion of the exposed second preliminary plate (see, e.g., the second preliminary plate PPL2 of FIG. 15) that does not overlap the patterned second hard mask MK2 in a thickness direction of the heat radiating member VC. In an embodiment, the second portion of the second preliminary plate PPL2 may be removed through an etching process. After forming the second openings OP2, the second hard mask MK2 may be removed.

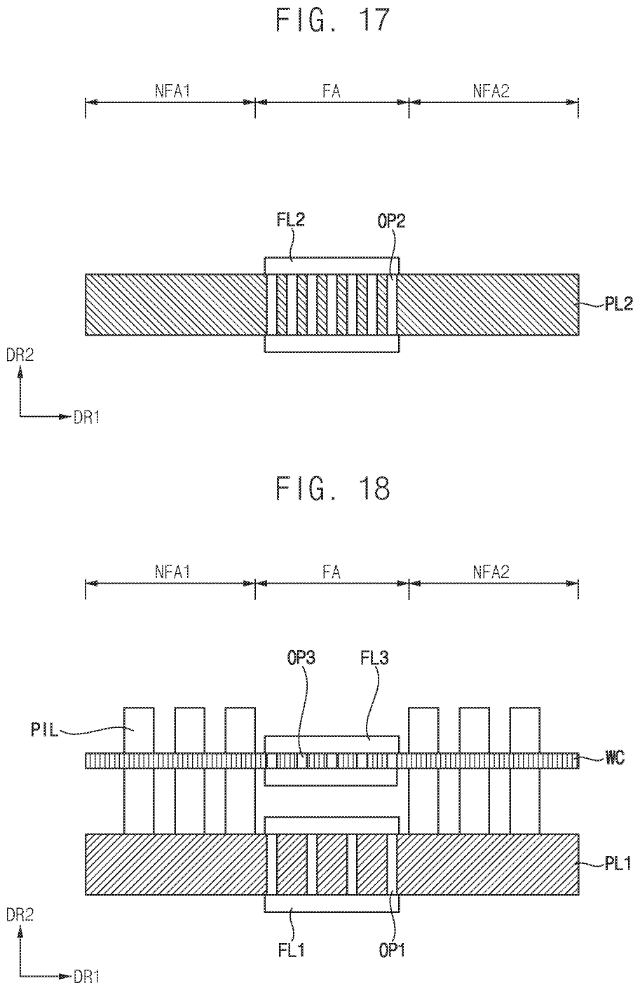

Referring to FIG. 17, a second film FL2 may be attached to upper and lower surfaces of a portion of the second plate PL2 in the folding area FA.

Referring to FIG. 18, the wick structure WC may be disposed such that the pillars PIL penetrate the wick structure WC. In an embodiment, the wick structure WC may be disposed (e.g., directly disposed) on the upper surface of the first plate PL1. For example, the distance L between the first plate PL1 and the wick structure WC may be about 0.

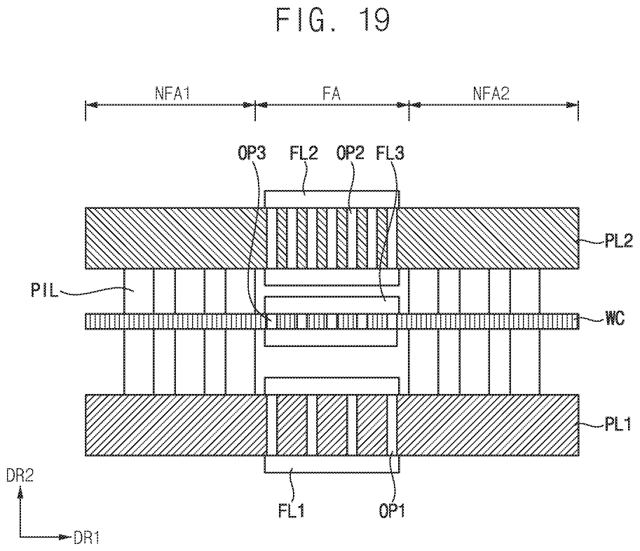

Referring to FIG. 19, a second plate PL2 may be disposed on the pillars PIL. In an embodiment, the first separation distance (see, e.g., the first separation distance L1 of FIG. 4) may be greater than the second separation distance (see, e.g., the second separation distance L2 of FIG. 4).

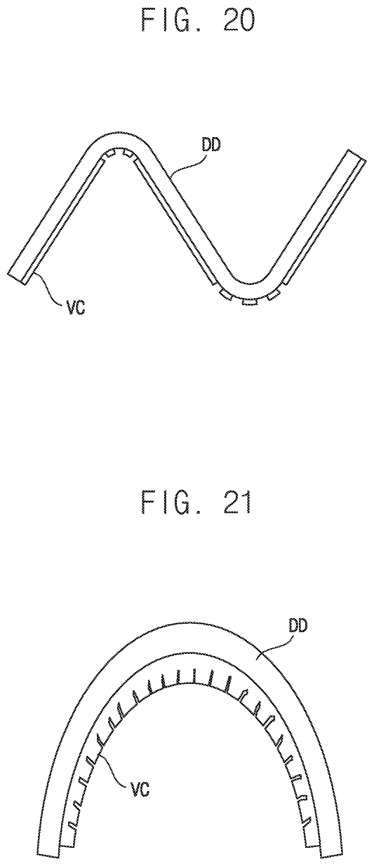

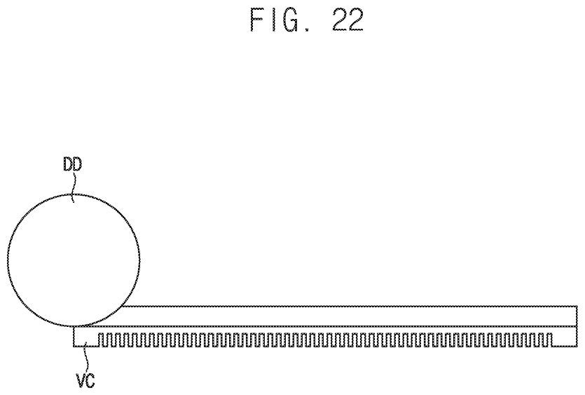

FIGS. 20 and 21 are views illustrating a multi-foldable display device with the heat radiating member of FIG. 1 according to an embodiment. FIG. 22 is a schematic view illustrating a rollable display device with the heat radiating member of FIG. 1 according to an embodiment.

Referring to FIGS. 20, 21, 22, and 4, the first separation distance L1 of the first plate PL1 and the second separation distance L2 of the second plate PL2 of the heat radiating member VC attached to the display device DD may be different according to a folding direction.

The disclosure can be applied to various display devices and various electronic devices including the display devices. For example, the disclosure may be applicable to smartphones, mobile phones, smart pads, smart watches, table PCs, vehicle navigation systems, televisions, computer monitors, laptops, or the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A heat radiating member comprising:
a first plate extending in a first direction and including:
a first non-folding area;
a second non-folding area; and
a folding area disposed between the first non-folding area and the second non-folding area and including a plurality of first openings;
a second plate extending in the first direction, spaced apart from the first plate in a second direction intersecting the first direction, and including a plurality of second openings in the folding area; and
a plurality of pillars disposed between the first plate and the second plate in the first non-folding area and the second non-folding area and connecting the first plate and the second plate,
wherein a first separation distance between two adjacent ones of the plurality of first openings and a second separation distance between two adjacent ones of the plurality of second openings are different in the first direction.

2. The heat radiating member of claim 1, further comprising:
a wick structure disposed between the first plate and the second plate, extending in the first direction, and including a plurality of third openings in the folding area.

3. The heat radiating member of claim 2, wherein a third separation distance between two adjacent ones of the plurality of third openings is greater than the second separation distance and less than the first separation distance in the first direction.

4. The heat radiating member of claim 1, wherein
the first plate and the second plate are folded with respect to a folding axis, and
a distance between the folding axis and the first plate is greater than a distance between the folding axis and the second plate.

5. The heat radiating member of claim 4, wherein the first separation distance is greater than the second separation distance.

6. The heat radiating member of claim 2, further comprising:
a first film attached to an upper surface and a lower surface of a portion of the first plate in the folding area;
a second film attached to an upper surface and a lower surface of a portion of the second plate in the folding area; and
a third film attached to an upper surface and a lower surface of a portion of the wick structure in the folding area.

7. The heat radiating member of claim 6, wherein the first film and the second film include thermoplastic polyurethane.

8. The heat radiating member of claim 2, wherein a portion of the wick structure in the first non-folding area and the second non-folding area includes a mesh structure.

9. The heat radiating member of claim 2, wherein the plurality of pillars penetrate the wick structure.

10. A heat radiating member comprising:
a first plate extending in a first direction and including:
a first non-folding area;
a second non-folding area; and
a folding area disposed between the first non-folding area and the second non-folding area and including a plurality of first openings;
a second plate extending in the first direction, spaced apart from the first plate in a second direction intersecting the first direction, and including a plurality of second openings in the folding area; and
a plurality of pillars disposed between the first plate and the second plate in the first non-folding area and the second non-folding area and connecting the first plate and the second plate,
wherein a width of each of the plurality of second openings is different from a width of each of the plurality of first openings in the first direction.

11. The heat radiating member of claim 10, further comprising:
a wick structure disposed between the first plate and the second plate, extending in the first direction, and including a plurality of third openings in the folding area.

12. The heat radiating member of claim 11, wherein a width of each of the plurality of third openings is greater than the width of each of the plurality of second openings and less than the width of each of the plurality of first openings in the first direction.

13. The heat radiating member of claim 10, wherein
the first plate and the second plate are folded with respect to a folding axis, and
a distance between the folding axis and the first plate is greater than a distance between the folding axis and the second plate.

14. The heat radiating member of claim 13, wherein the width of each of the plurality of first openings is greater than the width of each of the plurality of second openings.

15. A method of manufacturing a heat radiating member comprising:
forming a first preliminary plate extending in a first direction;
forming a first plate including a first non-folding area, a second non-folding area, and a folding area disposed between the first non-folding area and the second non-folding area and including a plurality of first openings by patterning a first portion of the first preliminary plate;
forming a plurality of pillars extending in a second direction intersecting the first direction on the first plate in the first non-folding area and the second non-folding area;
forming a preliminary wick structure extending in the first direction;
forming a wick structure including a plurality of third openings in the folding area by patterning a third portion of the preliminary wick structure;
forming a second preliminary plate extending in the first direction;
forming a second plate including a plurality of second openings in the folding area by patterning a second portion of the second preliminary plate;
disposing the wick structure on the first plate so that the plurality of pillars pass through the wick structure; and
disposing the second plate on the plurality of pillars,
wherein a first separation distance between two adjacent ones of the plurality of first openings and a second separation distance between two adjacent ones of the plurality of second openings are different in the first direction.

16. The method of claim 15 further comprising:
attaching a first film to an upper surface and a lower surface of a portion of the first plate in the folding area,
attaching a second film to an upper surface and a lower surface of a portion of the second plate in the folding area, and
attaching a third film to an upper surface and a lower surface of a portion of the wick structure in the folding area.

17. The method of claim 15, wherein the forming of the first plate includes:
forming a first hard mask on the first preliminary plate;
patterning a portion of the first hard mask overlapping the first portion of the folding area in a thickness direction of the heat radiating member;
etching the first preliminary plate; and
removing the first hard mask.

18. The method of claim 15, wherein the forming of the wick structure includes:
forming a second hard mask on the preliminary wick structure;
patterning a portion of the second hard mask in the third portion of the folding area;
etching the preliminary wick structure; and
removing the second hard mask.

19. The method of claim 15, wherein the forming of the second plate includes:
forming a second hard mask on the second preliminary plate;
patterning a portion of the second hard mask in the second portion of the folding area;
etching the second preliminary plate; and
removing the second hard mask.

20. The method of claim 15, wherein the first separation distance is greater than the second separation distance.
